(19) United States
(12) Patent Application Publication
(10) Pub. No.: US 2004/0209467 A1
(43) Pub. Date: Oct. 21, 2004

(54) METHOD FOR REDUCING PLASMA RELATED DAMAGES

(76) Inventors: SINCLAIR WANG, KAOHSIUNG (TW); HSUEH-HAO SHIH, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,582

(22) Filed: Apr. 21, 2003

(51) Int. Cl. H01L 21/302; H01L 21/461

(52) U.S. Cl. 438/689

(57) ABSTRACT

A method for reducing plasma charging damages on gate dielectric film is disclosed. Polysilicon with smaller grain size is formed over the gate dielectric film. Since the grain size is smaller, a low electric field is developed at the grain tip at the polysilicon/dielectric film interface. Local damages to the gate dielectric film are thus reduced.

### BACKGROUND OF INVENTION

1. Field of Invention

The present invention relates to a method for mitigating plasma related damages. More particularly, the present invention relates to a method for reducing plasma charging damage on insulating film.

2. Description of Related Art

Semiconductor integrated circuit devices normally include a thin dielectric material, which functions, for example, as a gate dielectric film for transistors. The gate dielectric film is typically formed on a semiconductor substrate over a region which will serve as a channel region. The transistors function when a channel is formed in the semiconductor substrate beneath the gate dielectric in response to a voltage being applied to a gate electrode formed above the gate dielectric film. The quality and integrity of the gate dielectric film is critical to the functionality of the transistor devices.

When semiconductor devices are manufactured, various plasma processes, which include dry etching, ashing, deposition by means of plasma CVD method and the like, are used. However, plasma processing also increases damage potential of the gate dielectric film because of charge buildup on conductors. The plasma that is generated in reaction chambers is supposedly designed to maintain a balance between the number of the positive charges and the number of the negative charges. However, there may be cases, usually caused by poor hardware or poor process conditions, in which the numbers of the positive and the negative charges are not balanced locally. In such cases, the charges in the plasma would flow into the semiconductor substrate via the gate electrode and the gate dielectric film. A large amount of current flow results in serious problems such as degradation or breakdown of the gate dielectric film. As feature sizes for devices decrease, the thickness of gate dielectric film decreases correspondingly, thereby further aggravating the adverse impact of plasma charging damages.

One prior art which deals with reducing plasma charging damages is described in U.S. Pat. No. 6,235,642 issued to Lee et al. In Lee et al., excess charges are collected and directed to a trench region for grounding. However, additional processes are needed to form the conduction channels for diverging charges to ground.

In another prior art approach shown in U.S. Pat. No. 6,159,864, Wang et al. disclose a method for preventing gate oxides from being damaged in a plasma-related process by performing a pre-determined plasma-related process to find damaged gate oxides. Based on damages of the damaged gate oxides, the predetermined plasma-related process is adjusted to prevent gate oxide on other semiconductor wafers from being damaged. Again, additional processes are needed to prevent plasma charging damages.

### SUMMARY OF INVENTION

Accordingly, the present invention provides a method to mitigate plasma charging damages, wherein local damages induced upon the gate insulating film is reduced.

The present invention also provides a method to mitigate plasma charging damages, wherein no additional process is required, while the quality and the integrity of the gate insulating film are maintained.

In accordance to the present invention, subsequent to the formation of a gate insulating film, for example, a gate oxide film, polysilicon with smaller grain size is formed over the gate insulating film. The grain size of polysilicon is, for example, less than 1000 angstroms. Since with a smaller grain size, a lower electric field is developed at the grain tip at the polysilicon/oxide interface. Local damage to the gate insulating film is thus reduced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A to 1B are schematic, cross-sectional views showing the method for reducing plasma charging damages on a dielectric thin film according to one aspect of the present invention; and

FIGS. 2A and 2B are transmission electron micrographs of polysilicon with larger grain size and polysilicon with smaller grain size, respectively.

### DETAILED DESCRIPTION

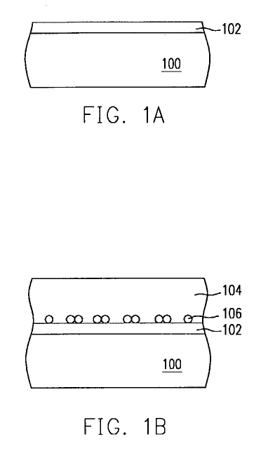

FIG. 1A to 1B are schematic, cross-sectional views showing the method for reducing plasma charging damages on a dielectric thin film according to one aspect of the present invention.

Referring to FIG. 1A, a substrate 100 is provided. The substrate 100 is, for example, a silicon substrate, which may include numerous devices formed thereon and therein. An insulating film 102 is then formed over the substrate 100. The insulting film 102 is, for example, a gate oxide layer, formed by oxidation or deposition.

Continue to FIG. 1B, a polysilicon layer 104 with a smaller grain size is formed over the dielectric film 102. Conventionally, the grain size of polysilicon is about 2000 angstroms to about several microns. The grain size of the polysilicon layer 104 of the present invention is, for example, less than 1000 angstroms. The polysilicon layer 104 with smaller grain size is formed by, for example, passing a gas source with 100 percent silane (SiH₄) or a mixture of SiH₄ gas and PH₃ gas. The gas source of SiH₄ is passed at a flow rate of about 80 to 150 sccm, where PH₃ is at a flow rate of about 0 to 100 sccm if an in-situ doped polysilicon film is formed. The deposition temperature is about 620 to 750 degrees Celsius, preferably at 720 degrees Celsius. The deposition time range is about 10 to 100 seconds, depending on the film thickness of polysilicon that is required. Hydrogen gas (H₂), at a flow rate of less than 3000 sccm, may also be introduced into the gas source to reduce surface impurities and moisture. As shown in FIG. 1B, since polysilicon with a smaller grain size can avoid a high electric field developed at the grain tip 106 at the polysillicon/oxide interface, localized damage induced upon the insulating film 104 is thus reduced.

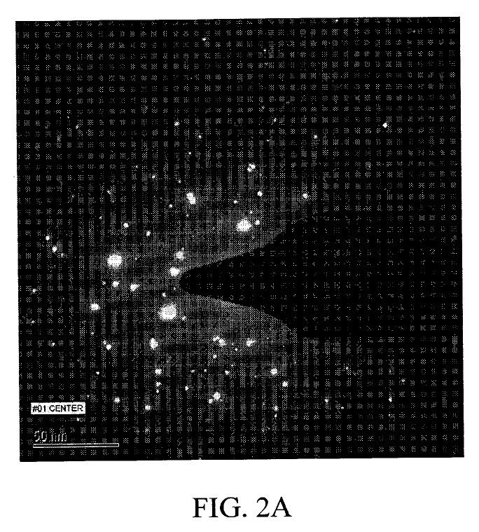

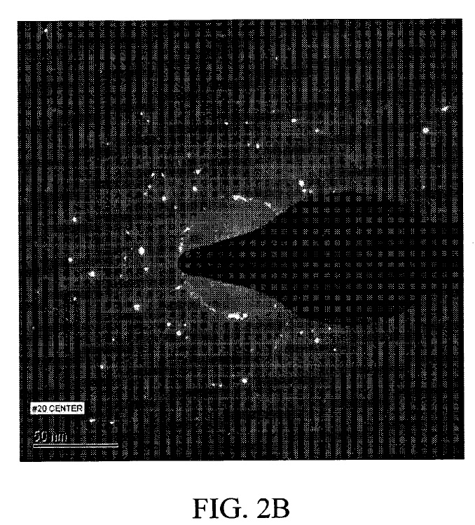

The quality and integrity of oxide films having polysilicon with a larger grain size or a smaller grain size, respectively, formed thereon are evaluated and compared subsequent to a plasma exposure. In accordance to the experiment conducted for the present invention, a silicon oxide film is grown to about 280 angstroms thick on a blanket wafer. In-situ doped polysilicon with either a larger grain size or a smaller grain size is further deposited over the silicon oxide film. The doped polysilicon is deposited to about 750 angstroms thick. The larger grain size polysilicon is ranged from about 2000 angstroms to several microns, while the smaller grain size polysilicon is about 300 to 600 angstroms. FIGS. 2A and 2B are transmission electron micrographs of polysilicon with larger grain size and polysilicon with smaller grain size, respectively. As shown in FIGS. 2A and 2B, polysilicon with a smaller grain size is shown to have small bright specks in a more continuous arrangement, while polysilicon with a greater grain size is shown to have bigger bright specks in a more scattered arrangement.

Undoped silicon glass is further deposited over the doped polysilicon. The undoped silicon glass is about 1000 angstroms thick, and is formed by plasma enhanced deposition. Thereafter, the undoped poysilicon glass and doped polysilicon are removed by wet etching. The silicon oxide film is then evaluated by flat band voltage (V_{fb}) and effective charge density (Q_{eff}) measurement by non-contact CV technology.

Table 1 summarizes the measured results of V_{fb} and Q_{eff} on the silicon oxide film having polysilicon with a larger grain size formed thereon and the silicon oxide having polysilicon with a smaller grain sized formed thereon, respectively.

TABLE 1

| Wafer Slot | | 1 | 2 |
|---|---|---|---|
| 280 Å silicon dioxide | | Yes | Yes |
| Doped polysilicon 750 Å (with larger grain size) | | No | Yes |
| Doped polysilicon 750 Å (with smaller grain size) | | Yes | No |
| 1000 Å PE-USG deposition | | Yes | Yes |
| USG and polysilicon removal | | Yes | Yes |
| Non-contact CV measurement. | Vtb (V) | −0.078 | −0.349 |
| (average of 9 data points) | Qeff(cm⁻²e¹⁰) | 7.45 | 29.84 |

As shown in Table 1, plasma damage is effectively reduced in the silicon oxide film when polysilicon with a smaller grain size is formed, as indicated from the measurements of flat band voltage (V_{fb}) and effective charge density (Q_{eff}) in the silicon oxide film.

The defect density (D₀) performance of a 30 Å gate oxide of the 0.18 μm mask ROM product formed with polysilicon of a larger grain size and polysilicon of a smaller grain size is also determined and the result is summarized in Table 2.

TABLE 2

| | | | | | | |
|---|---|---|---|---|---|---|
| | | | | | | Defect |
| Batch | Sample | Area per | Samples | | Total Area | density |
| No. | Size | sample (cm²) | Failed | Yield | (cm²) | (D₀) |

(a) With Polysilicon of Larger Grain Size

| | | | | | | |
|---|---|---|---|---|---|---|
| 1 | 360 | 0.0025 | 14 | 0.96111 | 0.9 | 15.8661 |
| 2 | 360 | 0.0025 | 20 | 0.94444 | 0.9 | 22.8634 |

(b) With Polysilicon of Smaller Grain Size

| | | | | | | |
|---|---|---|---|---|---|---|
| 1 | 360 | 0.0025 | 4 | 0.98889 | 0.9 | 4.46932 |
| 2 | 360 | 0.0025 | 3 | 0.99167 | 0.9 | 3.3473 |

The results of defect density performance also suggests that polysilicon with a smaller grain size would lead to a superior quality product and a higher yield.

According to the method for reducing plasma charging damage on insulating film of the present invention, since polysilicon with a smaller grain size is formed, a high electric field is thus avoided at the grain tip at the polysillicon/oxide interface during a plasma process. Localized damages induced upon the gate dielectric layer are thus reduced. Further, no additional process is required to mitigate the plasma charging damages.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for reducing plasma charging damages, comprising:
providing a dielectric film over a substrate; and
forming a polysilicon layer with a small grain size over the dielectric film, wherein the grain size of the polysilicon layer is less than 1000 angstroms.

2. The method of claim 1, wherein the polysilicon layer is formed with a gas source of SiH₄ at a flow rate of about 80 to 150 sccm, under a temperature of about 620 degrees to 750 degrees Celsius for about 10 to 100 seconds.

3. The method of claim 2, wherein the gas source also comprises a PH₃ gas at a flow rate of about 0 to 100 sccm.

4. The method of claim 2, wherein the gas source further comprises a hydrogen gas.

5. The method of claim 4, wherein a flow rate of the hydrogen gas is less than 3000 sccm.

6. The method of claim 1, wherein the polysilicon layer is amorphous or crystalline.
